(19) United States
(12) Patent Application Publication
(10) Pub. No.: US 2007/0131990 A1
(43) Pub. Date: Jun. 14, 2007

(54) System for manufacturing flat panel display

(75) Inventors: Taek-Yong Jang, Gyeonggi-do (KR); Byung-II Lee, Gyeonggi-do (KR); Young-Ho Lee, Gyeonggi-do (KR)

Correspondence Address: BACON & THOMAS, PLLC, 625 SLATERS LANE, FOURTH FLOOR, ALEXANDRIA, VA, 22314, US

(73) Assignee: TERASEMICON Corporation, Gyeonggi-do (KR)

(21) Appl. No.: 11/635,032

(22) Filed: Dec. 7, 2006

(30) Foreign Application Priority Data
Dec. 9, 2005 (KR) 10-2005-0120504

(51) Int. Cl. H01L 31/113

(52) U.S. Cl. 257/291

(57) ABSTRACT

A system for manufacturing a flat panel display includes a substrate storage part for storing a plurality of substrates; a first chamber including a substrate loading part for loading the plurality of substrates; a substrate transfer part, disposed between the substrate storage part and the first chamber, including an end effector for transferring the plurality of substrates between the substrate storage part and the substrate loading part; a second chamber including a source gas supplying part for uniformly supplying source gas to the entire surface of the plurality of substrates and a substrate heating part for heating the plurality of substrates; and a source powder supplying part including a source powder evaporating part for evaporating source powder in order to supply the source gas to the source gas supplying part and a source powder storage part for supplying the source powder to the source powder evaporating part.

### FIELD OF THE INVENTION

The present invention relates to a system for manufacturing a flat panel display. More particularly, the present invention relates to the system for manufacturing the flat panel display, the system being provided with a batch-type boat for processing large-area glass substrates, a transfer device for loading the glass substrates onto the batch-type boat, a reaction chamber having a heating device for processing a plurality of glass substrates and a gas supply system, a sealing system, and the like.

### BACKGROUND OF THE INVENTION

As well-known in the art, flat panel displays that are most widely used in recent years include LCD (Liquid Crystal Display) devices, PDP (Plasma Display Panel) devices, organic EL (Electroluminescent) display devices, and the like.

Among these display devices, the LCD devices are the flat panel displays widely used in that they have low power consumption due to low operating voltage and they are portable due to their small size although they require a backlight system unlike CRTs.

Color filters are employed in the LCD devices to embody various colors. Each of pixels in the filters is comprised of three subpixels, i.e., RGB, and matrix control methods may be applied to embody various colors through each of the subpixels.

Among LCD devices adopting the matrix control methods, an active matrix type LCD, e.g., a TFT (Thin Film Transistor) LCD, can achieve clear colors by using three transistors capable of processing red, green and blue signals for each pixel.

While typical LCD devices are manufactured, a photolithograpy technique is adopted to form, e.g., a thin film of ITO (Indium Tin Oxide) and an electrode pattern on the surface of an LCD substrate.

Thus, the process for manufacturing the LCD devices also includes a plurality of heat treatment steps.

For example, FIG. 1 shows a side conceptual view representing a chemical vapor deposition apparatus for an LCD glass substrate. Specifically, FIG. 1 depicts a single type chemical vapor deposition apparatus for depositing one glass substrate sequentially, having a vertical hot wall type reaction chamber.

Such a chemical vapor deposition apparatus can be largely divided into three sections: a reaction chamber for establishing a heat treatment environment; a supplying device for supplying a source gas to the reaction chamber; and a transferring device for loading a substrate into the reaction chamber while maintaining the cleanness of the environment.

That is, a stage 1 where a glass substrate 100 is placed in a standby state and a robot arm (i.e., end effector) 2 for transferring the glass substrate from the stage 1 are disposed.

A transfer chamber 3 and a load lock chamber, i.e., a standby chamber 5 are partitioned by a wall between the transfer chamber 3 and the standby chamber 5, and a gate 6 is installed through the wall.

Meanwhile, the standby chamber 5 is provided with a lifting device 7 for transferring a boat 4. The lifting device 7 includes a lifting rail and a driving device. The driving device is provided at a lower part of the boat 4, bypassing a heat transfer area of the reaction chamber.

Further, a flat-plate-shaped holder is installed on the boat 4, for the purpose of supporting the entire bottom surface of the substrate, thereby preventing the bending of the glass substrate during a heat treatment process and maintaining the flatness of the glass substrate.

Moreover, a heating device 9 for thermal decomposition of a reaction gas is installed in the reaction chamber 8. An inlet nozzle 10 and an exhaust nozzle 11 for injecting and exhausting a source gas are connected to the reaction chamber 8. Specifically, the inlet nozzle 10 is a shower-head type nozzle for uniformly distributing the source gas on the glass substrate.

Considering a source gas supplying device for depositing silicon onto the glass substrate 100, a source powder 13 is filled in an evaporation container 12 and then evaporated by a heater. A carrier gas is supplied into the evaporation container 12 so that source gas can be injected into the reaction chamber where a low-pressure environment may be established.

A conventional single type heat treatment system, in which heat treatment is carried out by loading one glass substrate into heat treatment reaction chamber, has a drawback in that the time required for the heat treatment is tremendously increased as the number of the glass substrates is increased.

Another method, e.g., a batch-type method, in which a plurality of substrates are stacked on a boat, also has a drawback in that a batch-type boat using a simple slit cannot be applied as it is, and thus, there arise some problems to be solved throughout the entire manufacturing system, e.g., the reaction chamber, the source gas supplying device, and the transfer device.

First, there is a difficulty in adopting a flat-plate-shaped holder for a batch-type boat to be loaded into the reaction chamber.

Specifically, the single type provides a loading/unloading space for an end effector by supporting a substrate on a flat panel (i.e., holder) and separating the substrate from the flat panel by using a lifting device.

However, unlike the single type, in case of a batch type in which a plurality of substrates are collectively processed, it is very complicated to provide such a lifting device for each substrate. Thus, in order to satisfy both a condition that a glass substrate should be supported and a condition that a working space for an end effector should be provided, a holder used only for a glass substrate and an end effector coupled therewith are required.

Furthermore, the diffusion of the source gas within the reaction chamber is unstable, and a CVD (Chemical Vapor Deposition) process involves the deposition process of the silicon onto the glass substrate by thermal decomposition, so that the main factors for determining the process may be a heat and a supplied source gas. Thus, the uniform flow of the reaction gas leads to the uniformity of the process.

However, in case glass substrates of a large-area are considered the flow of a source gas between the glass substrates may not be uniform.

Next, the source gas may not be supplied smoothly by the source gas supplying device.

That is, if a plurality of substrates are processed in a batch type, the source powder must not be filled into an evaporation container sufficiently. If a large amount of the source powder is filled into the evaporation container, the quality of the process may be degraded because powder dust itself is introduced into the reaction chamber.

Therefore, the amount of source powder to be filled into the evaporation container may be limited, and the time required for filling the source powder into the evaporation container may result in a decrease in productivity.

Although the above-mentioned problems may be solved by providing an evaporation container of the batch type, the size of the entire equipment is increased by adding the evaporation container and the heating device, which is not preferable to enhance the productivity.

Further, it is hard to manufacture the transfer device because the structure of the peripheral equipment thereof is complicated. Moreover, since a great number of substrates having a large area are loaded on the batch-type boat, it is difficult to get rid of waste gas in the standby chamber.

In general, the treatment process in the reaction chamber includes a standby time to exhaust toxic gases or other residual gases.

However, if a plurality of substrates are processed in the batch type, the exhaust time of the toxic gases would be lengthened, and thus, the standby time would be more required.

Moreover, the toxic gas cannot be removed, and thus, the leakage of the toxic gas cannot be avoided whether or not the standby chamber exists.

Therefore, a new system capable of reducing the process standby time and removing the toxic gases more efficiently is required.

### SUMMARY OF THE INVENTION

It is, therefore, an object of the present invention to provide a system for manufacturing a flat panel display capable of processing a plurality of large-area glass substrates in a batch type.

In accordance with one aspect of the present invention, there is provided a system for manufacturing a flat panel display, including: a substrate storage part for storing a plurality of substrates; a first chamber including a substrate loading part for loading the plurality of substrates along a vertical direction thereof; a substrate transfer part, disposed between the substrate storage part and the first chamber, including an end effector for transferring the plurality of substrates between the substrate storage part and the substrate loading part; a second chamber including a source gas supplying part for uniformly supplying source gas to the entire surface of the plurality of substrates and a substrate heating part for heating the plurality of substrates; and a source powder supplying part including a source powder evaporating part for evaporating source powder in order to supply the source gas to the source gas supplying part and a source powder storage part for supplying a predetermined amount of the source powder to the source powder evaporating part.

### BRIEF DESCRIPTION OF THE DRAWINGS

The above and other objects and features of the present invention will become apparent from the following description of preferred embodiments, given in conjunction with the accompanying drawings, in which:

FIG. 1 is a side conceptual view showing a conventional system for manufacturing a flat panel display;

FIG. 2 is an explanatory view showing a system for manufacturing a flat panel display in accordance with the present invention;

FIG. 3 is an explanatory view showing a batch-type boat and an end effector for mounting glass substrates on the boat in the manufacturing system of the present invention;

FIG. 4 is an explanatory view showing a dual boat as another example of the batch-type boat in accordance with another embodiment of the present invention; and

FIG. 5 is an explanatory view showing a reaction chamber having a heating device and a shower-head type nozzle mounted thereon in accordance with the present invention.

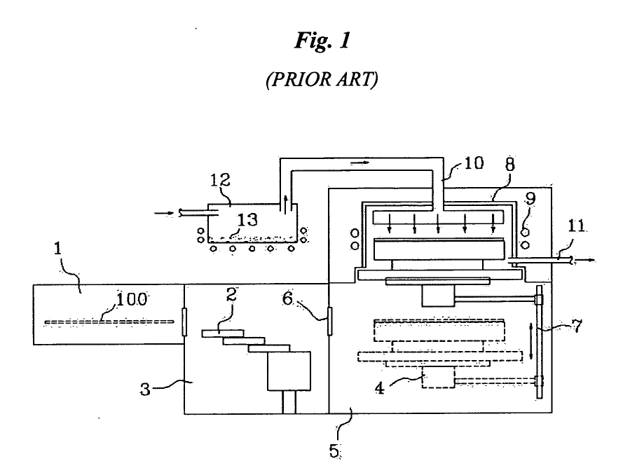

### DETAILED DESCRIPTION OF THE PREFERRED EMBODIMENT

The detailed description of the present invention illustrates specific embodiments in which the present invention can be performed with reference to the attached drawings.

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The configurations of the present invention for accomplishing the objects of the present invention are as follows.

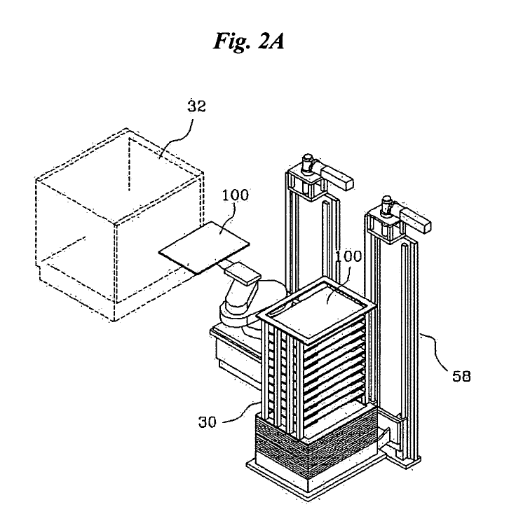

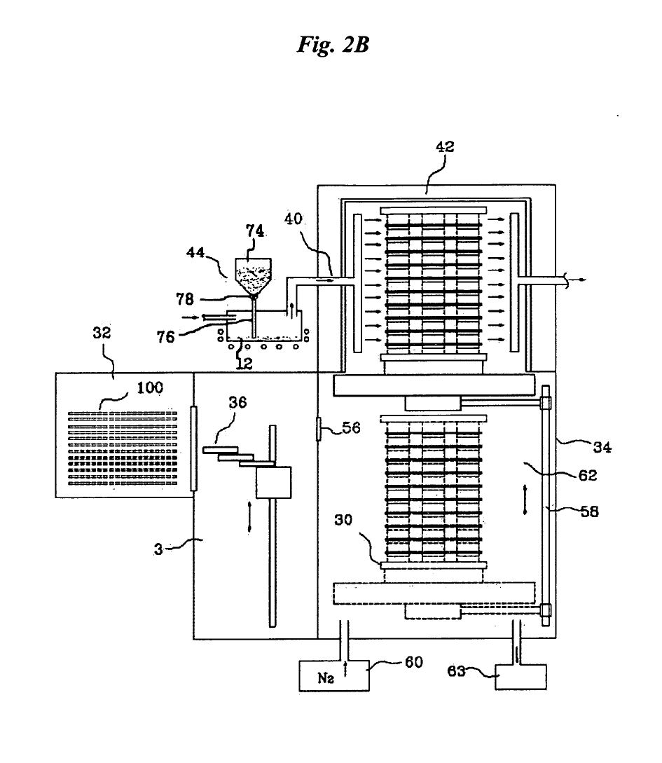

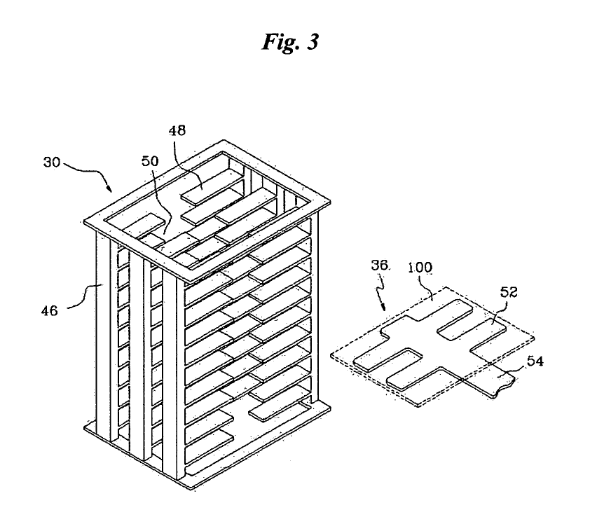

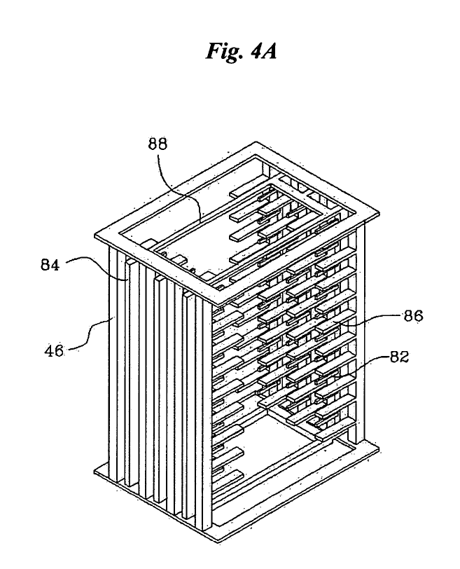

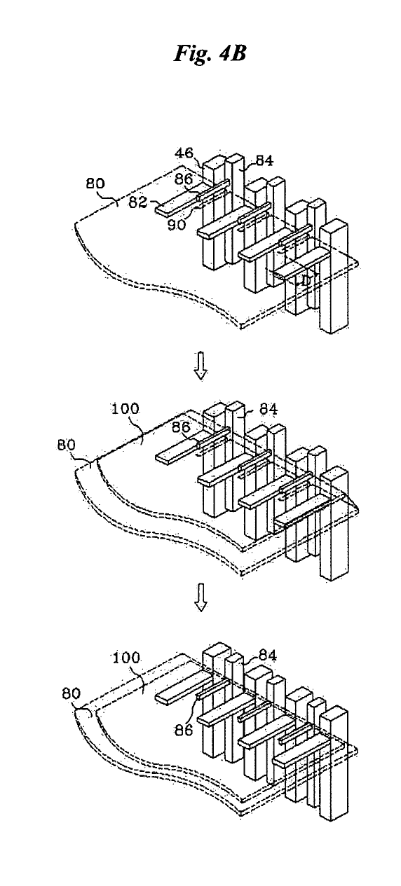

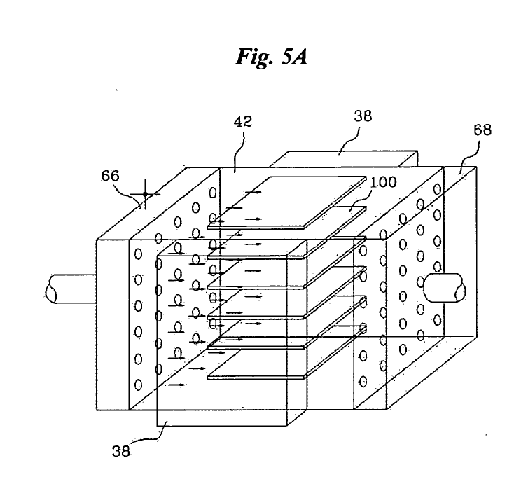

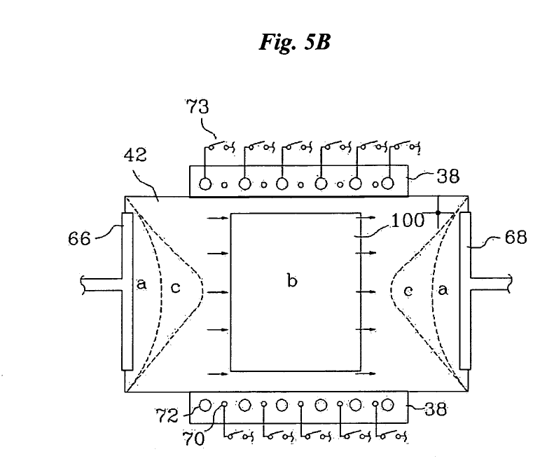

FIG. 2 is an explanatory view showing a system for manufacturing a flat panel display in accordance with the present invention; FIG. 3 is an explanatory view showing a batch-type boat and an end effector for loading glass substrates onto the boat in accordance with the present invention; FIG. 4 is an explanatory view showing a dual boat in accordance with another embodiment of the present invention; and FIG. 5 is an explanatory view showing a reaction chamber having a heating device and a shower-head type nozzle mounted thereon in accordance with the present invention.

The present invention provides a system for manufacturing a flat panel display including: a batch-type substrate loading boat 30 on which a plurality of glass substrates 100 are loaded; an end effector 36 for loading/unloading the glass substrates 100 onto/from the substrate loading boat 30 between a cassette stage 32 and a standby chamber 34; a reaction chamber 42 having a heating device 38 for supplying heat to the glass substrates 100 loaded on the batch-type substrate loading boat 30 and a nozzle device 40 for supplying a source gas to a region between the glass substrates; and a source powder supplying device 44 for filling a source powder into an evaporation container to process the plurality of glass substrates 100.

As shown in FIG. 3, the substrate loading boat 30 is provided with a boat frame 46 as a support rod arranged in a vertical or a longitudinal direction in order to load the plurality of glass substrates along the longitudinal direction. Moreover, the structure of the substrate loading boat 30 includes an opening for inserting and withdrawing the end effector 36. The vertical boat frame 46 is arranged at both lateral sides of the glass substrates 100. Further, substrate supporting panels 48 are protruded from both lateral sides of the boat frame 46 along a central direction, so that the bottom portion of the glass substrates 100 can be in contact with the substrate supporting panels 48. The central spaces between the substrate supporting panels 48 may function as bypass slits 50 which correspond to a path for moving the end effector 36 in the substrate loading boat 30.

Moreover, the end effector 36 includes a central supporting panel 54 formed along a specific direction and supporting panels 52 formed along a direction perpendicular to the specific direction, having the entire shape capable of passing through the bypass slits 50.

The substrate supporting panels 48 serve as supporters for supporting the bottom portion of the glass substrates 100 vulnerable to heat unlike semiconductor wafers, resulting in maintaining the flatness of the glass substrates 100 during a heat treatment process.

Further, as shown in FIG. 2B, a gate 56 having a width suitable for transferring a sheet of glass substrate is installed at the boundary between a transfer chamber 3 for loading/unloading the glass substrates 100 on the end effector 36 and the standby chamber 34. A lifting device 58 for introducing the boat 30 into the reaction chamber 42 may be ascended and descended to provide the glass substrates 100 to proper positions in the boat 30 through the gate 56.

The standby chamber 34 includes a purge gas supplying device 60 installed at one side thereof for eliminating the waste gas remaining therein after the process, a gas shielding unit 62 having inert gas supplied by the purge gas supplying device 60 and a purge gas exhausting device 63 installed at the other side thereof for exhausting a residual waste gas diluted by the inert gas.

The inert gas may include nitrogen, neon, argon, helium and the like.

Meanwhile, as shown in FIGS. 5A and 5B, the nozzle device 40 connected to the reaction chamber 42 includes a reaction tube 64 that provides a uniform pipeline capable of inducing a uniform flow of source gas, and a shower head-type nozzle 66 for supplying the flow of the reaction gas uniformly to the entire area of one cross section of the reaction tube 64. Further, the gas exhausting part is characterized in that shower head-type suction openings 68 are uniformly disposed in the entire area of the other cross section of the reaction tube 64 and connected to the vacuum pump.

Moreover, the reaction tube 64 is a rectangular parallelepiped serving as a linear uniform pipeline.

Further, the heating device 38 is divided into low-calorific hot wires 70 and high-calorific hot wires 72, which are attached to the reaction chamber 42 alternately. Respective powers are applied to each of the hot wires 70, 72.

The source powder supplying device 44 capable of maintaining a continuous process in the reaction chamber 42 includes a source powder storage container 74, located above the evaporation container 12, filled with source powder. Between the source powder storage container 74 and the evaporation container 12, a valve 78 and an inlet tube 76 are installed, which has the source powder introduced into the evaporation container 12 from the storage container 74 when the source powder in the storage container 74 is exhausted.

As described above, the present invention relates to a system for manufacturing a flat panel display. More particularly, the present invention relates to the system for manufacturing the flat panel display, the system being provided with a batch-type boat for processing large-area glass substrates, a transfer device for loading the glass substrates onto the batch-type boat, a reaction chamber having a heating device for processing a plurality of glass substrates and a gas supply system, a sealing system, and the like.

As shown in FIGS. 2 and 3, there are provided the batch-type substrate loading boat 30 for loading, i.e., piling up the plurality of glass substrates 100 at once and the end effector 36 for loading/unloading the glass substrate onto/from the substrate loading boat 30 between the cassette stage 32 and the standby chamber 34.

In accordance with another embodiment of the present invention, a flat-plate-shaped holder as shown in FIG. 4B may be installed at a dual boat of, e.g., FIG. 4A.

Planar holder bodies 80 for supporting the bottom surface of the glass substrates are disposed to maintain the flatness of the glass substrates during the heat treatment process. Moreover, a batch-type holder boat, including holder platforms 82 and the boat frame 46, capable of holding the holder bodies 80 to be piled up vertically. Further, a lifting boat 88, including substrate platforms 86 and lifting rods 84, is installed at the lifting device, may be used to ascend and descend the glass substrates 100 while avoiding interference with the holder boat. The dual boat is comprised of the holder boat and the lifting boat 88. In addition, penetrating slits 90 are formed in the holder bodies 80 so that the substrate platforms 86 can be penetrated to ascend and descend the glass substrates 100.

Since the holder bodies 80 are in contact with the most area of the glass substrates, the substrate platforms 86 for supporting the holder bodies 80 are not required to have a large surface like the substrate holding panel, but only required to have a surface enough to support the holder bodies 80.

The flat-plate-shaped holder bodies 80 supports the glass substrates 100 by using the substrate platforms 86, which cover the most area of the bottom portion of the glass substrates, thereby supporting the glass substrates more sufficiently.

Further, the shape of the end effector may be determined so as not to contact with the substrate platforms 86 ascended and descended through the penetrating slits 90, thereby minimizing the restrictions on the shape thereof.

However, the manufacturing expenses for a dual boat are increased.

In accordance with the above-mentioned embodiments of the present invention, the plurality of glass substrates can be loaded to be processed all at once.

Such a loading onto the boat 30 is performed through a single type gate 56 located between the transfer chamber 3 and the standby chamber 34, as shown in FIG. 2B.

The single type gate 56 provides an on-off door in which a vertical space for the transfer of the glass substrates is limited to one sheet among the glass substrates.

If a gate with a large size is installed, instead of the single type gate 56, for loading/unloading onto/from the batch-type boat 30 without adjusting the location of the batch-type boat 30, the manufacturing expenses for the gate are increased and the sealing of the standby chamber 34 us deteriorated.

Therefore, the single type gate 56 is required to be installed to get rid of the above-mentioned drawbacks of the gate with a large size, while ascending or descending the batch-type boat 30 by using the boat lifting device 58, to thereby provide a multi-stage loading position.

That is, the boat lifting device 58 serves as a pitch transfer device for loading/unloading of the glass substrates.

By the boat lifting device 58 functioning as the pitch transfer device, the glass substrates are loaded onto the batch-type boat 30, and then introduced into the reaction chamber 42.

The structures of the reaction chamber 42, the reaction tube 64, the shower-head type nozzle 66 and the suction openings 68 are determined as mentioned above.

Moreover, the reaction chamber 42, serving as a pipeline, induces a laminar flow of the source gas within the pipeline, and the glass substrates are disposed in this uniform flow of the source gas so that a great number of the glass substrates with a large surface can be processed within one pipeline.

Furthermore, the length of the reaction chamber 42, i.e., the length of the pipeline, may be determined such that the glass substrates are disposed at a reaction heat area (b) provided by a heater, while avoiding a cooling area (a) generated by the gas supply portion and the gas exhaust portion including a cooling device and an interface area (c) between the cooling area (a) and the reaction heat area (b) as shown in FIG. 5B. This is because the reaction gas is thermally decomposed to form a silicon thin film, resulting in blocking the shower-head type nozzle, when a reaction heat is supplied from a heater to the gas supply portion and the gas exhaust portion.

Spaces formed by the gas supply portion, the gas exhaust portion and a heating portion are comprised of the cooling area (a), the reaction heat area (b), and the interface area (c). However, at the interface area (c), the silicon thin film that is thinner and non-uniform in comparison with that of the reaction heat area may be formed and particles may be generated, which causes a bad effect on the system.

Moreover, the heating device 38 capable of having an influence upon the reaction heat area (b) may be divided into the low-calorific hot wires and the high-calorific hot wires which are in contact with the reaction chamber 42 alternately.

When the reaction chamber 42 for processing a great number of glass substrates having a large surface is prepared, it is hard to establish a proper heat environment during the process. For example, the proper heat environment should be 200 to 300° C. for a deposition process, 450 to 550° C. for an activation process, and 500 to 700° C. for a crystallization process.

Under the proper heat environment, various reaction heat areas are controlled by combining the above-mentioned two kinds of hot wires applicable under a high-temperature environment and a low-temperature environment. For the control of them, the high-calorific hot wires 72 and the low-calorific hot wires 70 are arranged alternately, thereby forming a heater block, and the respective switches are prepared to each of the hot wires, resulting in realizing the various reaction heat areas (a), (b), (c) in the reaction chamber 42 as mentioned above.

The source powder supplying device 44 capable of maintaining a continuous process in the reaction chamber 42 includes a source powder storage container 74, located above the evaporation container 12, filled with source powder. Between the source powder storage container 74 and the evaporation container 12, a valve 78 and an inlet tube 76 are installed, which has the source powder introduced into the evaporation container 12 from the storage container 74 when the source powder in the storage container 74 is exhausted.

The storage container 74 has a shape of a hopper, and the valve 78 is controlled by an actuator.

For example, an opening of the valve 78 supplies a predetermined amount of the source powder to the evaporation container 12 by rotating a driving shaft of the source powder supplying device 44.

The supply of the source powder to the evaporation container 12 is carried out by an injection tube, which is preferably disposed so as to prevent the source powder from being scattered.

The amount of the source powder to be filled into the evaporation container 12 may be determined by calculating the amount of the exhausted source powder, i.e., the amount of source gas which is diffused and deposited in the reaction chamber 42.

The deposition process is executed on the glass substrates 100 in the reaction chamber 42 by supplying the source gas thereto. Thereafter, the glass substrates 100 on the batch-type boat 30 are descended to the standby chamber 34, and then unloaded from the standby chamber 34 by the end effector 36.

The volume of the standby chamber 34 is considerably large because the boat 30 can be used to load a great number of glass substrates with a large area. Meanwhile, toxic materials, i.e., waste gases are generated in the reaction chamber 42 after the process thereat.

The standby chamber 34 includes a purge gas supplying device 60 installed at one side thereof for eliminating the waste gas remaining therein after the process, a gas shielding unit 62 having inert gas supplied by the purge gas supplying device 60 and a purge gas exhausting device 63 installed at the other side thereof for exhausting a residual waste gas diluted by the inert gas.

The inert gas may include nitrogen, neon, argon, helium and the like.

As a result, the exhaust time for the toxic gases becomes shortened and the toxic gases can be removed more effectively.

As described above, the system for manufacturing a flat panel display, in which the batch-type boat, the end effector, the reaction chamber having the shower-head type nozzle and the heating device, the source gas supplying device and the sealing device are provided, is capable of processing the great number of the glass substrates with a large surface.

While the present invention has been described with respect to the particular embodiments, it will be apparent to those skilled in the art that various changes and modifications may be made without departing from the spirit and scope of the invention as defined in the following claims.

What is claimed is:

1. A system for manufacturing a flat panel display, comprising:
a substrate storage part for storing a plurality of substrates;
a first chamber including a substrate loading part for loading the plurality of substrates along a vertical direction thereof;
a substrate transfer part, disposed between the substrate storage part and the first chamber, including an end effector for transferring the plurality of substrates between the substrate storage part and the substrate loading part;
a second chamber including a source gas supplying part for uniformly supplying source gas to the entire surface of the plurality of substrates and a substrate heating part for heating the plurality of substrates; and
a source powder supplying part including a source powder evaporating part for evaporating source powder in order to supply the source gas to the source gas supplying part and a source powder storage part for supplying a predetermined amount of the source powder to the source powder evaporating part.

2. The system of claim 1,
wherein the substrate loading part includes a frame, extending in a vertical direction thereof at lateral sides thereof, for having the end effector inserted into or withdrawn from the substrate loading part in order to transfer the plurality of substrates,
wherein support members, attached to the frame, are protruded toward a central line which bisects the substrates loaded on the substrate loading part and in contact with the bottom of the substrates to support the substrates, and
wherein a space between the support members corresponds to room for moving the end effector while loading and unloading the substrates.

3. The system of claim 2,
wherein the end effector includes a horizontal support member and a vertical support member which support the substrates while transferring the substrates, and
wherein the horizontal support member is formed along a direction in which the vertical support member extends.

4. The system of claim 1,
wherein a gate, through which the end effector passes, is installed at the interface between the substrate transfer part and the first chamber,
wherein the first chamber further includes a lifting part for transferring the substrate loading part to the second chamber, and
wherein the substrate loading part is ascended and descended such that a position of the gate at which each of the substrates is introduced to the first chamber corresponds to a location of the substrate loading part at which each of the substrates is desired to be loaded.

5. The system of claim 1, wherein the first chamber further includes:
a gas supplying part for supplying inert gas in order to eliminate waste gas which is generated in the second chamber during the process therein and then introduced into the first chamber;
a gas maintenance part for maintaining the first chamber under an inert gas atmosphere by supplying the inert gas from the gas supplying part; and
a gas exhaust part for exhausting the waste gas diluted by the inert gas from the first chamber.

6. The system of claim 5, wherein the inert gas is any one of nitrogen, neon, argon and helium.

7. The system of claim 1, wherein the second chamber further includes:
a reaction tube that provides a uniform pipeline, with a constant cross section, capable of having the source gas uniformly flown within the second chamber;
a shower-head type nozzle for introducing the source gas with a constant flow rate to one cross section of an inlet of the reaction tube; and
a shower-head type suction openings for exhausting the source gas to the other cross section of an outlet of the reaction tube.

8. The system of claim 7, wherein the reaction tube has a rectangular parallelepiped that provides a uniform pipeline.

9. The system of claim 1, wherein the substrate heating part includes a low-calorific hot wire and a high-calorific hot wire, which are installed on the reaction chamber alternately, respective powers being applied to each of the hot wires.

10. The system of claim 1,
wherein the source powder storage part, disposed at an upper side of the source powder evaporating part, and
wherein an inlet tube and a valve, for introducing a predetermined amount of the source powder into the source powder evaporating part from the storage powder storage part when the source powder in the source powder evaporating part is exhausted, are installed between the source powder evaporating part and the source powder storage part.
